(19) United States
(12) Patent Application Publication
(10) Pub. No.: US 2008/0132039 A1
(43) Pub. Date: Jun. 5, 2008

(54) FORMATION AND TREATMENT OF EPITAXIAL LAYER CONTAINING SILICON AND CARBON

(76) Inventors: YONAH CHO, Sunnyvale, CA (US); Yihwan Kim, Milpitas, CA (US)

Correspondence Address: DIEHL SERVILLA LLC, 77 BRANT AVENUE, SUITE 210, CLARK, NJ, 07066, US

(21) Appl. No.: 11/566,058

(22) Filed: Dec. 1, 2006

(51) Int. Cl. H01L 21/20

(52) U.S. Cl. 438/478

(57) ABSTRACT

Methods for formation and treatment of epitaxial layers containing silicon and carbon are disclosed. Treatment converts interstitial carbon to substitutional carbon in the epitaxial layer, according to one or more embodiments. Specific embodiments pertain to the formation and treatment of epitaxial layers in semiconductor devices, for example, Metal Oxide Semiconductor Field Effect Transistor (MOSFET) devices. In specific embodiments, the treatment of the epitaxial layer involves annealing for short periods of time, for example, by laser annealing, millisecond annealing, rapid thermal annealing, spike annealing and combinations thereof. Embodiments include amorphization of the epitaxial layer containing silicon and carbon.

### BACKGROUND

Embodiments of the present invention generally relate to formation and treatment of epitaxial layers containing silicon and carbon. Specific embodiments pertain to the formation and treatment of epitaxial layers in semiconductor devices, for example, Metal Oxide Semiconductor Field Effect Transistor (MOSFET) devices.

Typically, a Metal Oxide Semiconductor (MOS) transistor includes a semiconductor substrate, a source, a drain, and a channel positioned between the source and drain on the substrate, which is usually made from silicon. Normally, a gate stack is located above the channel, the gate stack being composed of a gate oxide layer or gate electrode located directly above the channel, a gate conductor material above the gate oxide layer, and sidewall spacers. The sidewall spacers protect the sidewalls of the gate conductor. The gate electrode is generally formed of doped polysilicon (Si) while the gate dielectric material may comprise a thin layer (e.g., <20 Å) of a high dielectric constant material (e.g., a dielectric constant greater than 4.0) such as silicon dioxide (SiO₂) or N-doped silicon dioxide, and the like.

The amount of current that flows through the channel of a MOS transistor is directly proportional to a mobility of carriers in the channel, and the use of high mobility MOS transistors enables more current to flow and consequently faster circuit performance. Mobility of the carriers in the channel of an MOS transistor can be increased by producing a mechanical stress in the channel. A channel under compressive strain, for example, a silicon-germanium channel layer grown on silicon, has significantly enhanced hole mobility to provide a pMOS transistor. A channel under tensile strain, for example, a thin silicon channel layer grown on relaxed silicon-germanium, achieves significantly enhanced electron mobility to provide an nMOS transistor.

An nMOS transistor channel under tensile strain can also be provided by forming one or more carbon-doped silicon epitaxial layers, which may be complementary to the compressively strained SiGe channel in a pMOS transistor. Thus, carbon-doped silicon and silicon-germanium epitaxial layers can be deposited on the source/drain of nMOS and pMOS transistors, respectively. The source and drain areas can be either flat or recessed by selective Si dry etching. When properly fabricated, nMOS sources and drains covered with carbon-doped silicon epitaxy imposes tensile stress in the channel and increases nMOS drive current.

To achieve enhanced electron mobility in the channel of nMOS transistors having a recessed source/drain using carbon-doped silicon epitaxy, it is desirable to selectively form the carbon-doped silicon epitaxial layer on the source/drain either through selective deposition or by post-deposition processing. Furthermore, it is desirable for the carbon-doped silicon epitaxial layer to contain substitutional C atoms to induce tensile strain in the channel. Higher channel tensile strain can be achieved with increased substitutional C content in a carbon-doped silicon source and drain. However, most of C atoms incorporated through typical selective Si:C epitaxy processes (for example at process temperature >700° C.) occupy non-substitutional (i.e. interstitial) sites of the Si lattice. By lowering growth temperature, a higher fraction of substitutional carbon level can be achieved (e.g. nearly 100% at growth temperature of 550° C.), however, the slow growth rate at these lower temperatures is undesirable for device applications, and such selective processing might not be possible at the lower temperatures.

Therefore, there is a need to provide methods to improve the substitutional carbon content in carbon-doped silicon epitaxial layers. Such methods would be useful in the manufacture of transistor devices.

### SUMMARY OF THE INVENTION

One embodiment of the present invention relates to methods of forming and processing epitaxial layers containing silicon and carbon. Other embodiments relate to methods manufacturing of fabricating transistor devices including epitaxial layers containing silicon and carbon.

In accordance with one embodiment of the present invention, a method of treating an epitaxial layer containing silicon and carbon on a substrate is provided, which comprises providing a substrate having an epitaxial layer containing carbon and silicon deposited on the substrate, the carbon including interstitial carbon; and annealing the substrate and epitaxial layer at a temperature from about 800° C. to about 1350° C. to convert at least a portion of the interstitial carbon in the epitaxial layer to substitutional carbon. According to one embodiment, the combined total amount of substitutional carbon (if present initially) and interstitial carbon is greater than about 2 atomic percent.

According to certain embodiments, the method may further comprise amorphizing the epitaxial layer. The amorphizing may be achieved by ion implantation or other suitable methods. In embodiments that include amorphization, the annealing can be performed by one or more of dynamic surface annealing, laser annealing, millisecond annealing, flash annealing or spike annealing. In one or more embodiments, the annealing occurs for less than 10 seconds. In other embodiments, the annealing occurs for less than 900 milliseconds. For example, the annealing may be performed by laser annealing or millisecond annealing for less than 900 milliseconds.

In other embodiments, the annealing is performed by laser annealing or millisecond annealing for less than 900 milliseconds followed by rapid thermal annealing for less than 10 seconds. In still other embodiments, the annealing is performed by rapid thermal annealing for less than 10 seconds followed by laser annealing or millisecond annealing for less than 10 seconds.

Methods of forming Si:C epitaxial may be utilized during a fabrication step of transistor manufacturing process. Embodiments of the invention pertain to a method of manufacturing a transistor comprising forming a gate dielectric on a substrate; forming a gate electrode on the gate dielectric; forming source/drain regions on the substrate having a second conductivity on opposite sides of the electrode and defining a channel region between the source/drain regions; depositing an epitaxial layer containing silicon and carbon directly on the source/drain regions, a portion of the carbon being substitutional carbon, the remainder of the carbon being interstitial carbon; and annealing the substrate and epitaxial layer at a temperature from about 800° C. to about 1350° C. convert at least a portion of the interstitial carbon in the epitaxial layer to substitutional carbon. In certain embodiments, the combined total amount of substitutional carbon and interstitial carbon is greater than about 2 atomic percent.

In certain embodiments, the method of making a transistor may further comprise amorphizing the epitaxial layer by ion implantation. The annealing may be performed by one or more of dynamic surface annealing, laser annealing, millisecond annealing, flash annealing or spike annealing. Variations of annealing described above may be utilized to manufacture a transistor.

The foregoing has outlined rather broadly certain features and technical advantages of the present invention. It should be appreciated by those skilled in the art that the specific embodiments disclosed may be readily utilized as a basis for modifying or designing other structures or processes within the scope present invention. It should also be realized by those skilled in the art that such equivalent constructions do not depart form the spirit and scope of the invention as set forth in the appended claims.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an HRXRD spectra showing structural change of an epitaxial layer containing silicon and carbon after amorphization;

FIG. 2 is a HRXRD spectra showing structural change of an epitaxial layer containing silicon and carbon after amorphization and a surface anneal at temperatures between 1100 and 1300° C.;

FIG. 3 is an HRXRD spectra showing structural change of an epitaxial layer containing silicon and carbon after amorphization and a surface anneal at temperatures between 1100 and 1300° C. and further processed for spike annealing;

FIG. 4 is a cross-sectional view of a field effect transistor pair in accordance with an embodiment of the invention; and

FIG. 5 is a cross-sectional view of the NMOS field effect transistor shown in FIG. 1 having additional layers formed on the device.

### DETAILED DESCRIPTION

Embodiments of the invention generally provide a method of forming and treating an epitaxial layer containing silicon and carbon. Other embodiments pertain to a method of manufacturing a transistor.

The method of forming and treating an epitaxial layer comprises providing a substrate having an epitaxial layer containing carbon and silicon deposited on the substrate, the carbon including interstitial carbon; and annealing the substrate and epitaxial layer at a temperature from about 800° C. to about 1350° C. to convert at least a portion of the interstitial carbon in the epitaxial layer to substitutional carbon. In one embodiment, the method of manufacturing a transistor comprises forming a gate dielectric on a substrate; forming a gate electrode on the gate dielectric; forming source/drain regions on the substrate having a second conductivity on opposite sides of the electrode and defining a channel region between the source/drain regions; depositing an epitaxial layer containing silicon and carbon directly on the source/drain regions, the carbon including interstitial carbon; and annealing the substrate and epitaxial layer at a temperature from about 800° C. to about 1350° C. to convert at least a portion of the interstitial carbon in the epitaxial layer to substitutional carbon. Epitaxial layers are distinguished from bulk substrates and polysilicon layers.

As used herein, epitaxial deposition refers to the deposition of a single crystal layer on a substrate, so that the crystal structure of the deposited layer matches the crystal structure of the substrate. Thus, an epitaxial layer or film is a single crystal layer or film having a crystal structure that matches the crystal structure of the substrate.

According to embodiments of the invention, the processing of the epitaxial films containing carbon and silicon increases substitutional C content of the film. Substitutional C content in the Si:C layer can be increased by converting as-deposited non-substitutional C atoms to substitutional Si lattice sites. Although the present invention is not intended to be bound by any particular theory, it is believed that such conversion of non-substitutional (or interstitial) C atoms to substitutional sites may be related to distribution of point defects such as vacancies, self interstitials, and other foreign interstitials as well as defect clusters. By changing initial (as-deposited) defect distribution and Si lattice to a structure favorable for more C atoms to occupy substitutional sites, the substitutional C content can be increased. It will be understood that reference to increasing the amount of substitutional carbon is not intended to limit the invention to as-deposited films that containing substitutional carbon. According to embodiments of the invention, the initially deposited epitaxial film may contain no substitutional carbon, and according to embodiments of the present invention, the film comprising interstitial carbon is treated to reduce the amount of interstitial carbon and to increase the substitutional carbon from zero in the as-deposited film. Such structural change and increase in substitutional C content can be achieved by the process sequences described herein.

In one or more embodiments, an epitaxial film containing silicon and carbon is formed and treated by amorphization and annealing as described further below. The epitaxial films may be formed by selective or non-selective epitaxial layer deposition.

In one or more embodiments, an increase in substitutional C content can be achieved by combination of implantation and anneal in the following exemplary process sequence: (1) Deposition of epitaxial layer(s) containing silicon and carbon with high total C concentration (>2%) by selective or non-selective deposition process; (2) Amorphization of the epitaxial layer containing silicon and carbon, for example, by implantation of an ion, such as Si. It is generally desired that the energy and dose are such that entire thickness of the epitaxial layer is amorphized without lattice crystallinity after the implantation; and (3) Annealing for less than 60 seconds, for example, dynamic surface anneal, millisecond anneal or laser anneal, dynamic surface anneal (DSA) chamber. In one or more embodiments, the anneal temperature can be above 1000° C. with various scan speed (or resident time) in the range of 10s and 100s mm/s. According to one or more embodiments, the methods to follow the sequential order, however, the process is not limited to the exact steps recited above. For example, other process steps can be inserted between steps as long as the order of process sequence is maintained. The individual steps of the process will now be described according to one or more embodiments.

### The Substrate

The substrate is typically a silicon substrate, and it can be a patterned substrate. Patterned substrates are substrates that include electronic features formed into or onto the substrate surface. The patterned substrate may contain monocrystalline surfaces and at least one secondary surface that is non-monocrystalline, such as polycrystalline or amorphous surfaces. Monocrystallino surfaces include the bare crystalline substrate or a deposited single crystal layer usually made from a material such as silicon, silicon germanium or silicon carbon. Polycrystalline or amorphous surfaces may include dielectric materials, such as oxides or nitrides, specifically silicon oxide or silicon nitride, as well as amorphous silicon surfaces.

### Epitaxial Deposition

The silicon carbon layer may be deposited using an epitaxial process in a suitable processing chamber such as an Epi RP or Centura, both of which are available from Applied Materials, Santa Clara, Calif. Generally, the process chamber is maintained at a consistent temperature throughout the epitaxial process. However, some steps may be performed at varying temperatures. The process chamber is kept at a temperature in the range from about 250° C. to about 1,000° C., for example, from about 500° C. to about 900° C. The appropriate temperature to conduct the epitaxial process may depend on the particular precursors used to deposit and/or etch the silicon and carbon-containing materials, and can be determined by a person skilled in the art. The process chamber is usually maintained at a pressure from about 0.1 Torr to about 200 Torr, The pressure may fluctuate during and between this deposition step, but is generally constant.

During the epitaxial deposition process, the substrate is exposed to a deposition gas to form an epitaxial layer on the monocrystalline surface while forming a polycrystalline layer on the secondary surfaces. The specific exposure time of the deposition process is determined in relation to the exposure time during the etching process, as well as particular precursors and temperature used in the process. Generally, the substrate is exposed to the deposition gas long enough to form a maximized thickness of an epitaxial layer while forming a minimal thickness of a polycrystalline layer that may be easily etched away during deposition.

The deposition gas contains at least a silicon source, a carrier gas, and a carbon source. In an alternative embodiment, the deposition gas may include at least one etchant, such as hydrogen chloride or chlorine.

The silicon source is usually provided into the process chamber at a rate in a range from about 5 sccm to about 500 sccm, for example, from about 10 sccm to about 300 sccm, and specifically from about 50 sccm to about 200 sccm, more specifically, about 100 sccm. Silicon sources useful in the deposition gas to deposit silicon and carbon-containing compounds include, but not limited to, silanes, halogenated silanes and organosilanes. Silanes include silane (SiH₄) and higher silanes with the empirical formula SiₓH₍₂ₓ₊₂), such as disilane (Si₂H₆), trisilane (Si₃H₈), and tetrasilane (Si₄H₁₀), as well as others. Halogenated silanes include compounds with the empirical formula X′_{y}SiₓH_{(2x+2-y)}, where X′═F, Cl, Br or I, such as hexachlorodisilane (Si₂Cl₆), tetrachlorosilane (SiCl₄), dichlorosilane (Cl₂SiH₂) and trichlorosilane (Cl₃SiH). Organosilanes include compounds with the empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂).

The silicon source is usually delivered into the process chamber along with a carrier gas. The carrier gas has a flow rate from about 1 slm (standard liters per minute) to about 100 slm, for example, from about 5 slm to about 75 slm, and specifically from about 10 slm to about 50 slm, for example, about 25 slm. Carrier gases may include nitrogen (N₂), hydrogen (H₂), argon, helium and combinations thereof. An inert carrier gas is preferred and includes nitrogen, argon, helium and combinations thereof. A carrier gas may be selected based on the precursor(s) used and/or the process temperature during the epitaxial process 120. Usually the carrier gas is the same throughout each step. However, some embodiments may use different carrier gases in particular steps.

The carbon source provided to the process chamber during step 120 with the silicon source arid carrier gas to form a silicon and carbon-containing compound, such as a silicon carbon material, is usually provided into the process chamber at a rate in the range from about 0.1 sccm to about 20 sccm, for example, from about 0.5 sccm to about 10 sccm, and more specifically from about 1 sccm to about 5 sccm, for example, about 2 sccm. Carbon sources useful to deposit silicon and carbon-containing compounds include, but not limited to, organosilanes, alkyls, alkenes and alkynes of ethyl, propyl and butyl. Such carbon sources include methylsilane (CH₃SiH₃), dimethylsilane ((CH₃)₂SiH₂), trimethylsilane ((CH3)3SiH), ethylsilane (CH₃CH₂SiH₃), methane (CH₄), ethylene (C₂H₄), ethyne (C₂H₂), propane (C₃H₈), propene (C₃H₆), butyne (C₄H₆), as well as others. The carbon concentration of an epitaxial layer is in the range from about 200 ppm to about 5 atomic %, for example, from about 1 atomic % to about 3 atomic %, more specifically at least about 2 atomic % or at least about 1.5 atomic %. In one embodiment, the carbon concentration may be graded within an epitaxial layer, preferably graded with a higher carbon concentration in the lower portion of the epitaxial layer than in the upper portion of the epitaxial layer. Alternatively, a germanium source and a carbon source may both be added into the process chamber with the silicon source and carrier gas to form a silicon and carbon-containing compound, such as a silicon germanium carbon material.

The deposition process is terminated. In one example, the process chamber may be flushed with a purge gas or the carrier gas and/or the process chamber may be evacuated with a vacuum pump. The purging and/or evacuating processes remove excess deposition gas, reaction by-products and other contaminates. In another example, once the deposition process has terminated, the etching process is immediately started without purging and/or evacuating the process chamber.

### Etching

An optional etching process may be performed. The etching process removes a portion of the epitaxial layer on the substrate surface. The etching process removes both epitaxial or monocrystalline materials and amorphous or polycrystalline materials. Polycrystalline layers, if any, deposited on the substrate surface are removed at a faster rate than the epitaxial layers. The time duration of the etching process is balanced with the time duration of the deposition process to result in net deposition of the epitaxial layer selectively formed on desired areas of the substrate. Therefore, the net result of the deposition process and etching process to form selective and epitaxially grown silicon and carbon-containing material while minimizing, if any, growth of polycrystalline material.

During the etching process, the substrate is exposed to the etching gas for a period of time in the range from about 10 seconds to about 90 seconds, for example, from about 20 seconds to about 60 seconds, and more specifically from about 30 seconds to about 45 seconds. The etching gas includes at least one etchant and a carrier gas. The etchant is usually provided into the process chamber at a rate in the range from about 10 sccm to about 700 sccm, for example from about 50 sccm to about 500 sccm, The etchant used in the etching gas may include chlorine (Cl₂), hydrogen chloride (HCl), boron trichlornde (BCl₃), methylchloride (CH3Cl), carbon tetrachloride (CCl₄), chlorotrifluoride (ClF₃) and combinations thereof. Preferably, chlorine or hydrogen chloride is used as the etchant.

The etchant is usually provided into the process chamber with a carrier gas. The carrier gas has a flow rate in the range from about 1 slm to about 100 slm, for example, from about 5 slm to about 75 slm, and more specifically from about 10 slm to about 50 slm, for example, about 25 slm. Carrier gases may include nitrogen (N₂), hydrogen (H₂), argon, helium and combinations thereof. In some embodiment, an inert carrier gas is preferred and includes nitrogen, argon, helium and combinations thereof. A carrier gas may be selected based upon specific precursor(s) and/or temperature used during the epitaxial process.

The etching process is terminated. In one example, the process chamber may be flushed with a purge gas or the carrier gas and/or the process chamber may be evacuated with a vacuum pump. The purging and/or evacuating processes remove excess etching gas, reaction by-products and other contaminates. In another example, once the etching process has terminated, the thickness of the epitaxial layer is immediately started without purging and/or evacuating the process chamber.

The thicknesses of the epitaxial layer and the polycrystalline layer may be determined. If the predetermined thicknesses are achieved, then epitaxial process is terminated. However, if the predetermined thicknesses are not achieved, then the deposition process is repeated as a cycle until the desired thicknesses are achieved. The epitaxial layer is usually grown to have a thickness at a range from about 10 Å to about 2,000 Å, for example, from about 100 Å to about 1,500 Å, and more specifically from about 400 Å to about 1,200 Å, for example, about 800 Å. The polycrystalline layer is usually deposited with a thickness, if any, in a range from an atomic layer to about 500 Å. The desired or predetermined thickness of the epitaxial silicon and carbon-containing layer or the polycrystalline silicon and carbon-containing layer is specific to a particular fabrication process. In one example, the epitaxial layer may reach the predetermined thickness while the polycrystalline layer is too thick.

### Dopant Exposure

During epitaxial deposition, the epitaxial layer may optionally be exposed to a dopant. Typical dopants may include at least one dopant compound to provide a source of elemental dopant, such as boron, arsenic, phosphorous, gallium or aluminum. Dopants provide the deposited silicon and carbon-containing compounds with various conductive characteristics, such as directional electron flow in a controlled and desired pathway required by the electronic device. Films of the silicon and carbon-containing compounds are doped with particular dopants to achieve the desired conductive characteristic. In one example, the silicon and carbon-containing compound is doped p-type, such as by using diborane to add boron at a concentration in the range from about 10¹⁵ atoms/cm³ to about 10²¹ atoms/cm³. In one example, the p-type dopant has a concentration of at least 5×10¹⁹ atoms/cm³. In another example, the p-type dopant is in the range from about 1×10²⁰ atoms/cm³ to about 2.5×10²¹ atoms/cm³. In another example, the silicon and carbon-containing compound is doped n-type, such as with phosphorous and/or arsenic to a concentration in the range from about 10¹⁵ atoms/cm³ to about 10²¹ atoms/cm³.

A dopant source is usually provided into the process chamber during step 130. Boron-containing dopants useful as a dopant source include boranes and organoboranes. Boranes include borane, diborane (B₂H₆), triborane, tetraborane and pentaborane, while alkylboranes include compounds with the empirical formula RₓBH₍₃₋ₓ₎, where R=methyl, ethyl, propyl or butyl and x=1, 2 or 3. Alkylboranes include trimethylborane ((CH₃)₃B), dimethylborane ((CH₃)₂BH), triethylborane ((CH₃CH₂)₃B) and diethylborane ((CH₃CH₂)₂BH). Dopants may also include arsine (AsH₃), phosphine (PH₃) and alkylphosphines, such as with the empirical formula RₓPH₍₃₋ₓ₎, where R=methyl, ethyl, propyl or butyl and x=1, 2 or 3. Alkylphosphines include trimethylphosphine ((CH₃)₃P), dimethylphosphine ((CH₃)₂PH), triethylphosphine ((CH₃CH₂)₃P) and diethylphosphine ((CH₃CH₂)₂PH.

### Amorphization

The dopants may be introduced via a process such as ion implantation. Ion implantation may be used to form doped regions such as the source and the drain, which also results in amorphization of the epitaxial layer, particularly during the formation of lightly doped drain regions or source drain extensions as part of a transistor fabrication process. Amorphization is commonly performed with Si, Ge, or As ion implantation. The amorphization depth is determined by ion energy of implanting species. As is known in the art, a minimum dose is required to cause amorphization of crystalline Si, for example, 1E15 cm² with Si implantation. For n-type doping of Si:C source/drain, the thickness of the doped regions would be decided by desired S/D junction depth, which is typically less than 1000 Å. The impurity concentration may be greater than 1E20 atoms/cm³ or higher, and the doping dose may be greater than 2E15 cm⁻².

Amorphization of the epitaxial layer containing silicon and carbon may be achieved by in a Quantum X implanter available from Applied Materials, Santa Clara, Calif. Ion implantation amorphizes the initial Si:C epilayer (crystal structure) by displacing substitutional Si and C atoms to non-substitutional sites.

### Annealing

According to one or more embodiments of the invention, the epitaxial layer is annealed. In specific embodiments, the annealing may take place for a relatively short period of time such as in a rapid thermal anneal or rapid thermal processing chamber. As used herein, rapid thermal annealing (RTA) and rapid thermal processing (RTP) both refer to a process that subjects a sample to a very short yet highly controlled thermal cycle that heats the sample from room temperature to a high temperature, for example, as high as 1200° C. The duration of the thermal cycle during a RTP or RTA process is typically less than about 60 seconds, and typically less than about 30 seconds. In certain embodiments, the duration of the RTP or RTA is less than about 20 seconds, 15 seconds, 10 seconds, or 5 seconds. Spike annealing of flash annealing refers to a process in which a sample is exposed to high temperatures for less than about 10 seconds or 5 seconds. For example, a flash anneal or spike anneal may occur for less than about five seconds at high temperature of between about 800 degrees Celsius to 1200 degrees Celsius. Laser annealing or millisecond annealing refer to processes that subject a sample to a thermal cycle that heats the sample from room temperature to a high temperature, for example, as high as 1200° C., in less than about 900 milliseconds, and more typically less than about 500 milliseconds. As the name implies, laser annealing uses a laser to heat the sample.

The annealing process may include a rapid thermal process such as rapid thermal annealing, rapid thermal processing, laser annealing, millisecond annealing, and/or spike annealing or flash annealing or combinations thereof. The annealing temperature may depend on the process used. For example, spike annealing may have a temperature ranging between about 1000° C. and about 1100° C., preferably about 1050° C., while solid phase epitaxy may be performed at 500° C. or less.

The annealing process may include a spike anneal, such as rapid thermal process (RTP), laser annealing or thermal annealing with an atmosphere of gas, such as oxygen, nitrogen, hydrogen, argon, helium or combinations thereof. The annealing process is conducted at a temperature from about 800° C. to about 1200° C., preferably from about 1050° C. to about 1100° C. The annealing process may occur immediately after the silicon and carbon-containing layer is deposited or after a variety of other process steps the substrate will endure.

In one embodiment, spike annealing is performed in an RTP system capable of maintaining gas pressure in the annealing ambient at a level significantly lower than the atmospheric pressure. An example of such an RTP system is the RADIANCE CENTURA® system commercially available from Applied Materials, Inc., Santa Clara, Calif. Spike annealing is further discussed in commonly assigned U.S. Pat. No. 6,897,131, issued May 24, 2005, entitled ADVANCES IN SPIKE ANNEAL PROCESSES FOR ULTRA SHALLOW JUNCTIONS and commonly assigned U.S. Pat. No. 6,803,297, issued Oct. 12, 2004 entitled OPTIMAL SPIKE ANNEAL AMBIENT, which are herein incorporated by reference to the extent they do not conflict with the current specification and claims.

It has been observed that millisecond or laser annealing above 1000° C. in Applied Materials DSA chamber/system provided excellent results: Millisecond or laser annealing provides sufficient energy to bring non-substitutional C atoms back to substitutional sites to increase the substitutional carbon content of the epitaxial layer.

The processes of the invention can be carried out in equipment known in the art. The apparatus may contain multiple gas lines to maintain the deposition gas and the other process gases prior to entering the process chamber. Thereafter, the gases are brought into contact with a heated substrate on which the silicon and carbon-containing compound films are grown. Hardware that can be used to deposit silicon and carbon-containing films includes the Epi Centura® system and the Poly Gen® system available from Applied Materials, Inc., located in Santa Clara, Calif. An ALD apparatus is disclosed in U.S. Pat. No. 6,916,398 assigned to Applied Materials, Inc., and entitled, “Gas Delivery Apparatus and Methods for ALD,” and is incorporated herein by reference in entirety for the purpose of describing the apparatus. Other apparatuses include batch, high-temperature furnaces, as known in the art.

### EXAMPLES

### Example 1

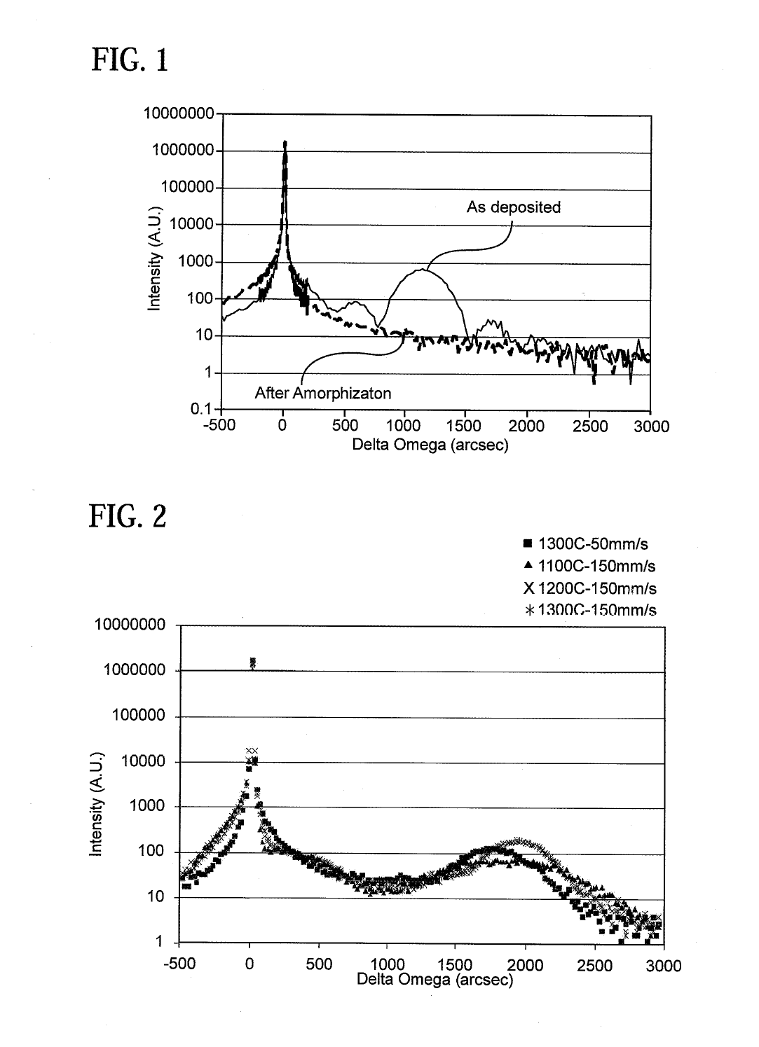

A 300 mm bare silicon wafer was placed in a 300 mm Epi Centura reduced pressure chamber, available from Applied Materials, Inc. of Santa Clara, Calif. A 500 Å thick undoped Si:C epitaxial film was deposited on the 300 mm bare silicon wafer. As-deposited Si:C film contains 2.3% total C, while 1.2% C is substitutional as indicated by film peak position around 1200 arcsec in high resolution X-ray diffractometer (HR-XRD) measurement in FIG. 1. The film is then subjected to Si ion implantation at 25 keV ion energy and a dose of 1.5×10¹⁵ cm² in Applied Materials' Quantum X implanter. Si implantation is performed to amorphize the Si:C epi layer.

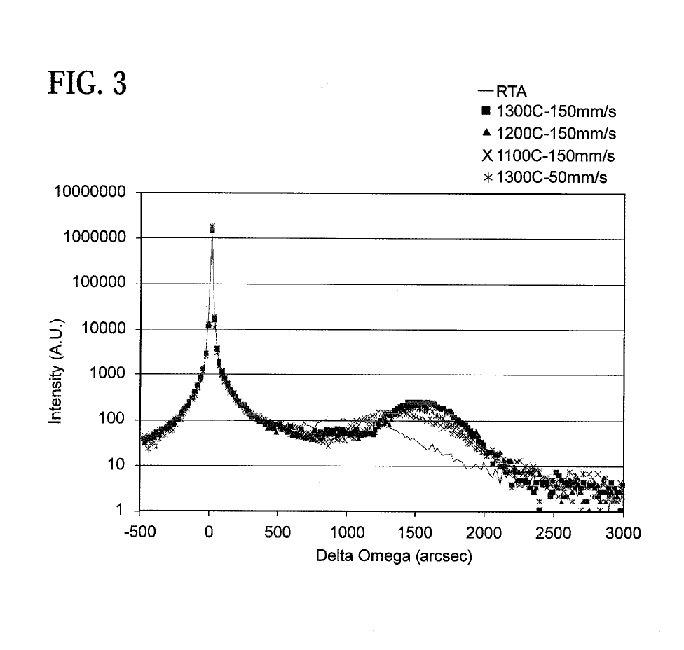

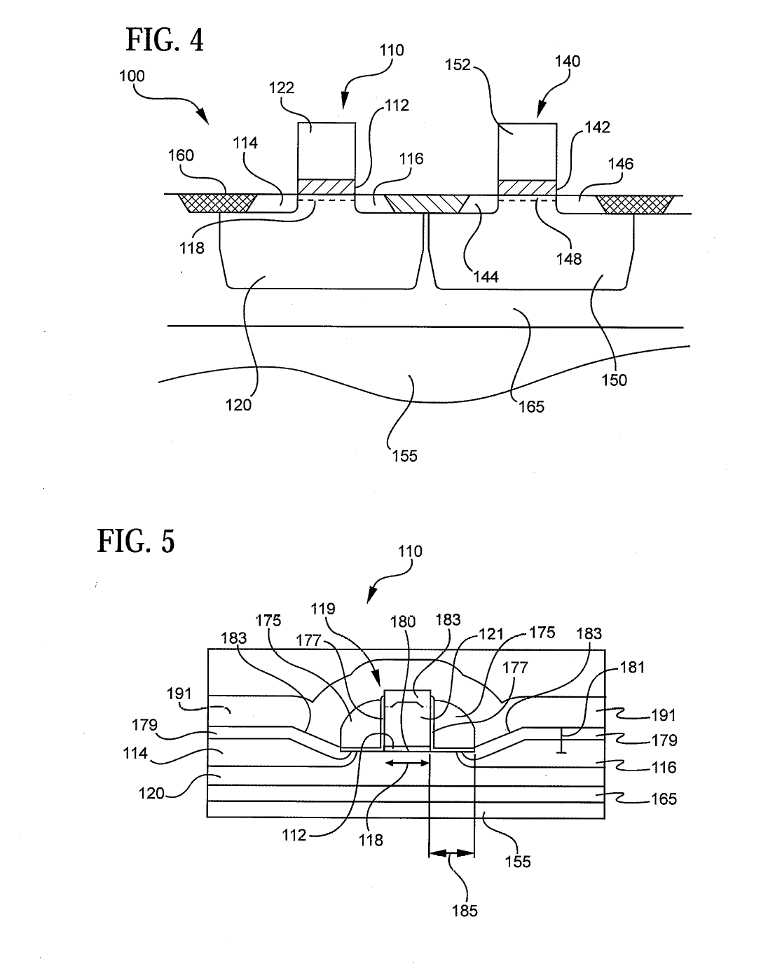

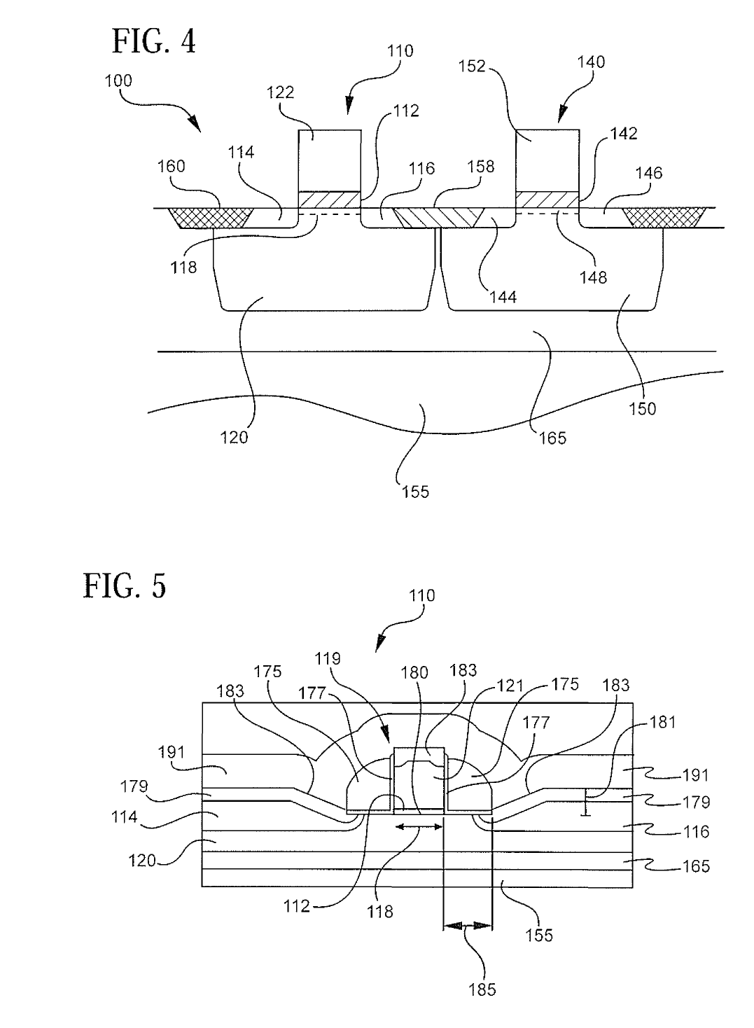

FIG. 1 shows a high resolution x-ray diffraction (HR-XRD) scan after the Si implant yields no film peak, but only shows the reference Si peak at 0 arcsec corresponding to the Si substrate, indicating the absence of the initial crystalline Si:C epitaxial layer. The amorphized structure is then annealed in Applied Materials' Dynamic Surface Anneal system in the temperature range between 1100-1300° C. at the scanning speed of 150 m/s or 50 m/s. As seen in FIG. 3, appearance of a peak around 2000 arcsec indicates crystalline layer formation of substitutional C of 2% after the DSA. The sample Si wafer is further processed for spike annealing at 1050° C. in a 10% O₂ and 90% N₂ ambient using a Centura RTP. As seen in FIG. 4, the substitutional C level of the annealed (DSA+spike) samples is about 1.5% compared to as-deposited level of 1.2%.

In FIG. 1, high resolution x-ray diffraction (XRD) scan of Si:C films show the structural change of as deposited Si:C epi layer after amorphization by Si implantation (step 2). As-deposited Si:C film peak at 1160 arcsec corresponds to 1.16% substitutional C in the film. After Si implantation, Si:C epilayer peak appears. This is an indication of crystallinity loss or amorphization.

### Example 2

FIG. 2 shows the XRD of the same Si:C sample after surface anneal at temperatures between 1100 and 1300° C. and scanning speeds of 50-150 mm/s. A new film peak at 1800-2000 arcsec corresponds to 1.8-2% substitutional C appears after DSA. The observed 1.8-2% substitutional C is higher than the initial 1.16% substitutional C content in the as-deposited Si:C layer shown in FIG. 2.

Thus, this example demonstrates the increased substitutional C content in Si:C is maintained at the level above the as-deposited substitutional C content even after conventional dopant activation anneal at up to 1050° C. by following the above process sequence prior to activation anneal. According to one or more embodiments, a proposed overall process sequence to maintain increased substitutional C is Si:C epitaxial layer deposition, followed by amorphization by implantation, followed by dynamic surface anneal, followed by spike anneal up to 1050° C.

### Example 3

FIG. 3 shows HRXRD of Si:C layer after the proposed 4 step sequence. Peak position at 1500 arcsec indicates substitutional C content of 1.5%, higher than as-deposited content of 1.16% shown in FIG. 1. Sample process through the above sequence without the surface anneal is labeled as “RTA only” and shows film peak position below 1000 arcsec representing substitutional C less than 1%. Therefore, increased substitutional C was not achieved by conventional spike anneal alone, but with surface anneal or surface anneal followed by spike anneal.

One or more embodiments of the present invention provide methods that are particularly useful in forming complementary metal oxide semiconductor (CMOS) integrated-circuit devices and will be described in that context. Other devices and applications are also within the scope of the invention. FIG. 4 illustrates portions of a cross sectional view of a FET pair in a typical CMOS device. Device 100 comprises a semiconductor substrate after forming wells to provide source/drain regions, gate dielectric, and gate electrode of an NMOS device and PMOS device. The device 100 can be formed using conventional semiconduictor processes such as growing single crystal silicon and formation of shallow trench isolation structures by trench etching and growing or depositing dielectric in the trench openings. Detailed procedures for forming these various structures are known in the art and are not described further herein.

Device 100 comprises a semiconductor substrate 155, for example, a silicon substrate, doped with a p-type material, a p-type epitaxial silicon layer 165 on substrate 155, a p-type well region 120 and an n-type well region 150 defined in epitaxial layer 165, an n-type transistor (NMOS FET) 110 defined in p-well 120 and a p-type transistor (PMOS FET) 140 defined in n-well 150. First isolation region 158 electrically isolates NMOS 110 and PMOS 140 transistors, and second isolation region 160 electrically isolates the pair of transistors 110 and 140 from other semiconductor devices on substrate 155.

According to one or more embodiments of the invention, NMOS transistor 110 comprises a gate electrode 122, first source region 114 and a drain region 116. The thickness of the NMOS gate electrode 122 is scalable and may be adjusted based on considerations related to device performance. NMOS gate electrode 122 has a work function corresponding to the work function of a N-type device. The source and drain regions are n-type regions on opposite sides of the gate electrode 122. Channel region 118 is interposed between source region 114 and drain region 116. A gate dielectric layer 112 separates channel region 118 and gate electrode 122. Processes for forming the NMOS gate electrode 122 and dielectric layer are known in the art and are not discussed further herein.

According to one or more embodiments, PMOS transistor 140 comprises a gate electrode 152, a source region 144 and a drain region 146. The thickness of the PMOS gate electrode 152 is scalable and may be adjusted based on considerations related to device performance. PMOS gate electrode 152 has a work function corresponding to the work function of a N-type device. The source and drain regions are p-type regions on opposite sides of gate electrode 152. Channel region 148 is interposed between source region 144 and drain region 146. A gate dielectric 142 separates channel region 148 and gate electrode 152. Dielectric 142 electrically insulates gate electrode 152 trom channel region 148. It will be appreciated that the structures of the transistors 110 and 140 shown in FIG. 4 and described immediately above are exemplary only, and various variants in materials, layers, etc. are within the scope of the present invention.

Referring now to FIG. 5, which shows a view of additional details of the NMOS device 110 of FIG. 4 after formation of spacers, layers over the source/drain regions, for example, silicide layers, and formation of the etch stop. It will be appreciated that the PMOS device shown in FIG. 4 may contain similar spacers and layers that may be tailored in dimensions and/or composition to affect the stress induced in the channel of the NMOS device as will be described further below. However, for illustration purposes, only NMOS device is shown and described in detail.

FIG. 5 shows spacers 175 that may be formed from suitable dielectric material incorporated around the gate 119. Offset spacers 177 may also be provided, which surround each of the spacers 175. Processes for forming shapes, sizes, and thickness of spacers 175 and 177 are known in the art and are not further described herein. A metal silicide layer 179 may be formed over the source region 114 and drain region 116. The silicide layer 179 may be formed from a suitable metal such as nickel, titanium, or cobalt by any suitable process such as sputtering or PVD (Physical Vapor Deposition). The silicide layer 179 may diffuse into portions of the underlying surfaces. Elevation of the drain region 116 is shown by the arrow 181, which is shown as the distance from the substrate surface 180 to the top of the silicide layer 179. Facet 183 of source drain region is shown as the angled surface As will be understood by the skilled artisan, the exemplary device described above may be modified to include a source/drain or source/drain extension having a Si:C epitaxial layer that may be further modified according to the methods described herein.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A method of treating an Si:C epitaxial layer on a substrate comprising:
providing a substrate having an epitaxial layer containing carbon and silicon deposited on the substrate, the carbon including interstitial carbon; and
amorphizing the epitaxial layer and annealing the substrate and epitaxial layer at a temperature from about 800° C. to about 1350° C. to convert at least a portion of interstitial carbon in the epitaxial layer to substitutional carbon.

2. The method of claim 1, wherein the combined total amount of substitutional carbon and interstitial carbon is greater than about 1 atomic percent.

3. The method of claim 1, wherein the amorphization is achieved by ion implantation.

4. The method of claim 1, wherein annealing is performed by one or more of dynamic surface annealing, laser annealing, millisecond annealing, flash annealing or spike annealing.

5. The method of claim 4, wherein annealing occurs for less than 10 seconds.

6. The method of claim 4, wherein the annealing occurs for less than 900 milliseconds.

7. The method of claim 3, wherein the annealing is performed by laser annealing of millisecond annealing for less than 900 milliseconds.

8. The method of claim 3, wherein the annealing is performed by laser annealing of millisecond annealing for less than 900 milliseconds followed by rapid thermal annealing for less than 10 seconds.

9. The method of claim 3, wherein the annealing is performed by rapid thermal annealing for less than 10 seconds followed by laser annealing or millisecond annealing for less than 10 seconds.

10. The method of claim 1, wherein the Si:C epitaxial layer is formed during a fabrication step of transistor manufacturing process, and the method further comprises:
forming a gate dielectric on a substrate;
forming a gate electrode on the gate dielectric;
forming source/drain regions on the substrate on opposite sides of the electrode and defining a channel region between the source/drain regions; and
depositing the epitaxial layer containing silicon and carbon directly on the source/drain regions, the carbon including interstitial carbon.

11. The method of claim 10, wherein the combined total amount of substitutional carbon and interstitial carbon is greater than about 1 atomic percent.

12. The method of claim 10, further comprising amorphizing the epitaxial layer by ion implantation.

13. The method of claim 12, wherein annealing is performed by one or more of dynamic surface annealing, laser annealing, millisecond annealing, flash annealing or spike annealing.

14. The method of claim 13, wherein annealing occurs for less than 10 seconds.

15. The method of claim 13, wherein the annealing is performed by laser annealing of millisecond annealing for less than 900 milliseconds.

16. The method of claim 13, wherein the annealing is performed by laser annealing of millisecond annealing for less than 900 milliseconds followed by rapid thermal annealing for less than 10 seconds.

17. The method of claim 13, wherein the annealing is performed by rapid thermal annealing for less than 10 seconds followed by laser annealing or millisecond annealing for less than 10 seconds.
